(19) United States
(12) Patent Application Publication
(10) Pub. No.: US 2025/0017096 A1
(43) Pub. Date: Jan. 9, 2025

(54) DISPLAY PANEL AND DISPLAY DEVICE

(71) Applicants: Huizhou China Star Optoelectronics Display Co., Ltd., Huizhou (CN); Shenzhen China Star Optoelectronics Semiconductor Display Technology Co., Ltd., Shenzhen (CN)

(72) Inventor: Min Wang, Huizhou (CN)

(21) Appl. No.: 17/620,295

(22) PCT Filed: Dec. 9, 2021
(86) PCT No.: PCT/CN2021/136705

§ 371 Date: Aug. 25, 2024

(30) Foreign Application Priority Data
Nov. 29, 2021 (CN) 202111448136.5

(51) Int. Cl. H10K 77/10; H10K 59/122; H10K 59/40; H10K 59/80; H10K 102/00

(52) U.S. Cl. CPC H10K 77/111; H10K 59/122; H10K 59/40; H10K 59/873; H10K 2102/311

(57) ABSTRACT

A display panel and a display device are disclosed. The display panel includes a substrate, a first flexible layer, a thin-film transistor (TFT) structural layer, a light-emitting functional layer, an opening, and a first inorganic layer. The opening penetrates the first flexible layer, the TFT structural layer, and the light-emitting functional layer. The first inorganic layer is disposed on a surface of the light-emitting functional layer away from the TFT structural layer and at least covers a lateral wall of the opening.

### FIELD OF INVENTION

The present disclosure relates to the field of display technologies, and more particularly, to a display panel and a display device.

### BACKGROUND OF INVENTION

Flexible organic light-emitting diode (OLED) display panels have unique advantages such as power saving, color performance, and portability, and have been increasingly used in cell phones, notebooks, and televisions.

Currently, there are two ways to install cameras on a display screen of OLED display panels. One is installing cameras under a screen, and another is defining a hole on a screen. The second one is a mainstream technology. Because OLED display panels are extremely sensitive to moisture and oxygen, encapsulation technologies are vital. Conventional OLED display panels are encapsulated by a structure of inorganic layer/organic layer/inorganic layer. However, opening positions where cameras are defined have a different encapsulation structure, which makes moisture and oxygen easily enter the opening positions. Therefore, black spots are formed at the opening positions.

Therefore, it is necessary to provide a novel technology to solve the above technical issues.

### SUMMARY OF INVENTION

### Technical Issue

Embodiments of the present disclosure provide a display panel and a display device to solve a following issue: black spots are formed at opening positions because moisture and oxygen enter the opening positions.

### Solution for the Issue

### Technical Solution

An embodiment of the present disclosure provides a display panel, comprising a display area and a non-display area, wherein the non-display area comprises a through-hole, and the display panel comprises:
a substrate;
a first flexible layer, wherein the first flexible layer is disposed on the substrate;
a thin-film transistor (TFT) structural layer, wherein the TFT structural layer is disposed on a surface of the first flexible layer away from the substrate and is disposed in the display area;
a light-emitting functional layer, wherein the light-emitting functional layer is disposed on a surface of the TFT structural layer away from the first flexible layer;
an opening, wherein the opening is defined in the non-display area and penetrates the first flexible layer, the TFT structural layer, and the light-emitting functional layer; and
a first inorganic layer, wherein the first inorganic layer is disposed on a surface of the light-emitting functional layer away from the TFT structural layer and at least covers a lateral wall of the opening.

In the display panel provided by an embodiment of the present disclosure, the first inorganic layer covers a bottom of the opening.

In the display panel provided by an embodiment of the present disclosure, the display panel comprises:
a second inorganic layer, wherein the second inorganic layer is disposed on a surface of the first inorganic layer away from the light-emitting functional layer, and the second inorganic layer covers the first inorganic layer.

In the display panel provided by an embodiment of the present disclosure, the display panel comprises:
an undercut structure disposed in the non-display area, wherein the undercut structure is disposed on the substrate and comprises undercut space.

In the display panel provided by an embodiment of the present disclosure, the first flexible layer corresponding to the non-display area comprises at least two recesses, and a protrusion part is defined between two adjacent recesses;
the TFT structural layer comprises a buffer layer, the buffer layer is disposed on a side of the first flexible layer away from the substrate, the buffer layer comprises a spacer part disposed in the non-display area, and the protrusion part and the spacer part disposed above the protrusion part form the undercut structure;
the spacer part comprises a hovering part protruding from the protrusion part, and the hovering part and a lateral surface of the protrusion part form the undercut space; and
the recesses are communicatively connected to the undercut space.

In the display panel provided by an embodiment of the present disclosure, the light-emitting functional layer comprises an anode, a pixel defining layer, a light-emitting layer, and a cathode, which are sequentially disposed, the anode is electrically connected to the TFT structural layer, and at least part of the light-emitting layer is confined in an opening of the pixel defining layer;
the light-emitting layer corresponding to the non-display area comprises a first part and a second part, the first part of the light-emitting layer and the second part of the light-emitting layer are separated apart from each other by the undercut space, the first part of the light-emitting layer is disposed in the recesses, and the second part of the light-emitting layer is disposed on the spacer part; and
the cathode corresponding to the non-display area comprises a first part and a second part, the first part of the cathode and the second part of the cathode are separated from each other by the undercut space, the first part of the cathode is disposed on the first part of the light-emitting layer, and the second part of the cathode is disposed on the second part of the light-emitting layer.

In the display panel provided by an embodiment of the present disclosure, the first inorganic layer covers the recesses and the undercut structure.

In the display panel provided by an embodiment of the present disclosure, the recesses comprise a first recess and a second recess, the first recess is defined on a side of the second recess away from the through-hole, and the second recess is defined on a side close to the through-hole, and the display panel comprises:
an organic filling layer, wherein the organic filling layer fills the second recess; and
an organic encapsulation layer, wherein the organic encapsulation layer is disposed between the first inorganic layer and the second inorganic layer, and the organic encapsulation layer fills the first recess.

In the display panel provided by an embodiment of the present disclosure, the substrate comprises:
a backplate;
a second flexible layer, wherein the second flexible layer is disposed on the backplate;
a blocking layer, wherein the blocking layer is disposed on a surface of the second flexible layer away from the backplate, and the through-hole penetrates the backplate, the second flexible layer, and the blocking layer.

In the display panel provided by an embodiment of the present disclosure, a width of the opening is greater than or equal to 30 μm.

An embodiment of the present disclosure further provides a display device, comprising a touch control unit and a display panel, wherein the touch control unit is disposed on the display panel or is integrated into the display panel, the display panel comprises a display area and a non-display area, the non-display area comprises a through-hole, and the display panel comprises:
a substrate;
a first flexible layer, wherein the first flexible layer is disposed on the substrate;
a thin-film transistor (TFT) structural layer, wherein the TFT structural layer is disposed on a surface of the first flexible layer away from the substrate and is disposed in the display area;
a light-emitting functional layer, wherein the light-emitting functional layer is disposed on a surface of the TFT structural layer away from the first flexible layer;
an opening, wherein the opening is defined in the non-display area and penetrates the first flexible layer, the TFT structural layer, and the light-emitting functional layer; and
a first inorganic layer, wherein the first inorganic layer is disposed on a surface of the light-emitting functional layer away from the TFT structural layer and at least covers a lateral wall of the opening.

In the display device provided by an embodiment of the present disclosure, the first inorganic layer covers a bottom of the opening.

In the display device provided by an embodiment of the present disclosure, the display panel comprises:
a second inorganic layer, wherein the second inorganic layer is disposed on a surface of the first inorganic layer away from the light-emitting functional layer, and the second inorganic layer covers the first inorganic layer.

In the display device provided by an embodiment of the present disclosure, the display panel comprises:
an undercut structure disposed in the non-display area, wherein the undercut structure is disposed on the substrate and comprises undercut space.

In the display device provided by an embodiment of the present disclosure, the first flexible layer corresponding to the non-display area comprises at least two recesses, and a protrusion part is defined between two adjacent recesses;
the TFT structural layer comprises a buffer layer, the buffer layer is disposed on a side of the first flexible layer away from the substrate, the buffer layer comprises a spacer part disposed in the non-display area, and the protrusion part and the spacer part disposed above the protrusion part form the undercut structure;
the spacer part comprises a hovering part protruding from the protrusion part, and the hovering part and a lateral surface of the protrusion part form the undercut space; and
the recesses are communicatively connected to the undercut space.

In the display device provided by an embodiment of the present disclosure, the light-emitting functional layer comprises an anode, a pixel defining layer, a light-emitting layer, and a cathode, which are sequentially disposed, the anode is electrically connected to the TFT structural layer, and at least part of the light-emitting layer is confined in an opening of the pixel defining layer;
the light-emitting layer corresponding to the non-display area comprises a first part and a second part, the first part of the light-emitting layer and the second part of the light-emitting layer are separated apart from each other by the undercut space, the first part of the light-emitting layer is disposed in the recesses, and the second part of the light-emitting layer is disposed on the spacer part; and
the cathode corresponding to the non-display area comprises a first part and a second part, the first part of the cathode and the second part of the cathode are separated from each other by the undercut space, the first part of the cathode is disposed on the first part of the light-emitting layer, and the second part of the cathode is disposed on the second part of the light-emitting layer.

In the display device provided by an embodiment of the present disclosure, the first inorganic layer covers the recesses and the undercut structure.

In the display device provided by an embodiment of the present disclosure, the recesses comprise a first recess and a second recess, the first recess is defined on a side of the second recess away from the through-hole, and the second recess is defined on a side close to the through-hole, and the display panel comprises:
an organic filling layer, wherein the organic filling layer fills the second recess; and
an organic encapsulation layer, wherein the organic encapsulation layer is disposed between the first inorganic layer and the second inorganic layer, and the organic encapsulation layer fills the first recess.

In the display device provided by an embodiment of the present disclosure, the substrate comprises:
a backplate;
a second flexible layer, wherein the second flexible layer is disposed on the backplate;
a blocking layer, wherein the blocking layer is disposed on a surface of the second flexible layer away from the backplate, and the through-hole penetrates the backplate, the second flexible layer, and the blocking layer.

In the display device provided by an embodiment of the present disclosure, a width of the opening is greater than or equal to 30 μm.

To clearly illustrate the above contents of the present disclosure, detailed descriptions are described below in conjunction with embodiments and drawings.

### Advantages of Invention

### Advantages

embodiments of the present disclosure provide a display panel and a display device. The display panel provided by the present embodiment includes a substrate, a first flexible layer, a TFT structural layer, a light-emitting functional layer, an opening, and a first inorganic layer. The first inorganic layer is disposed on the substrate. The TFT structural layer is disposed on a surface of the first flexible layer away from the substrate and is disposed in a display area. The light-emitting functional layer is disposed on a surface of the TFT structural layer away from the first flexible layer. The opening is defined in a non-display area and penetrates the first flexible layer, the TFT structural layer, and the light-emitting functional layer. The first inorganic layer is disposed in a surface of the light-emitting functional layer away from the TFT structural layer and at least covers a lateral wall of the opening. In the display panel provided by the embodiment of the present disclosure, the opening is defined on a side close to a through-hole. The opening penetrates the first flexible layer, the TFT structural layer, and the light-emitting functional layer. The first inorganic layer covers the lateral wall of the opening. Therefore, an issue of black spots formed at opening positions because moisture and oxygen enter the opening positions is solved.

### BRIEF DESCRIPTION OF DRAWINGS

### Description of Drawings

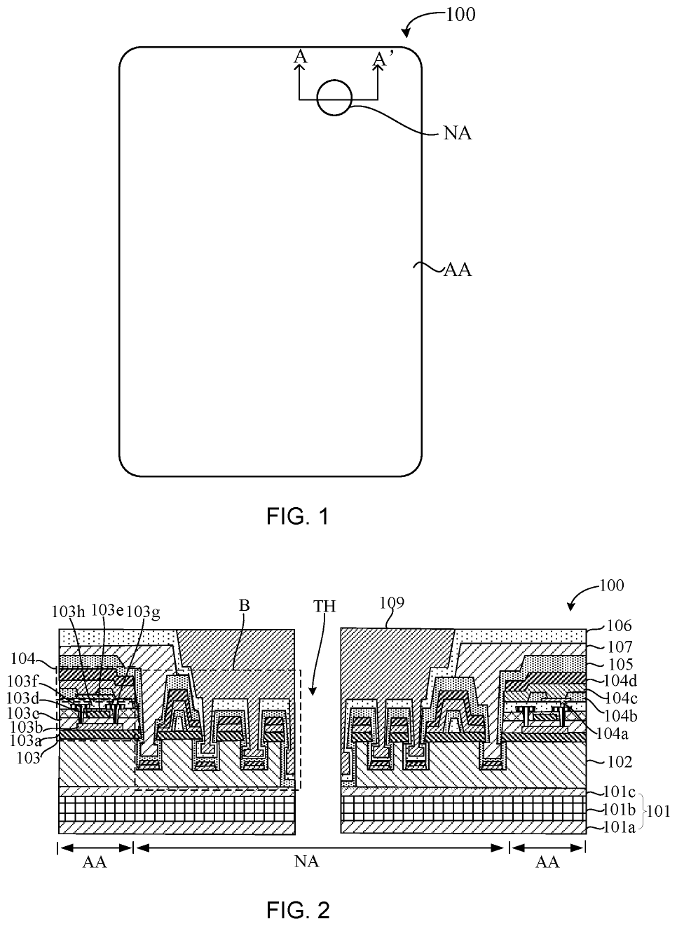

FIG. 1 is a plan structural view showing a display panel provided by an embodiment of the present disclosure.

FIG. 2 is a structural schematic view showing a cross-section of FIG. 1 taken along A-A′.

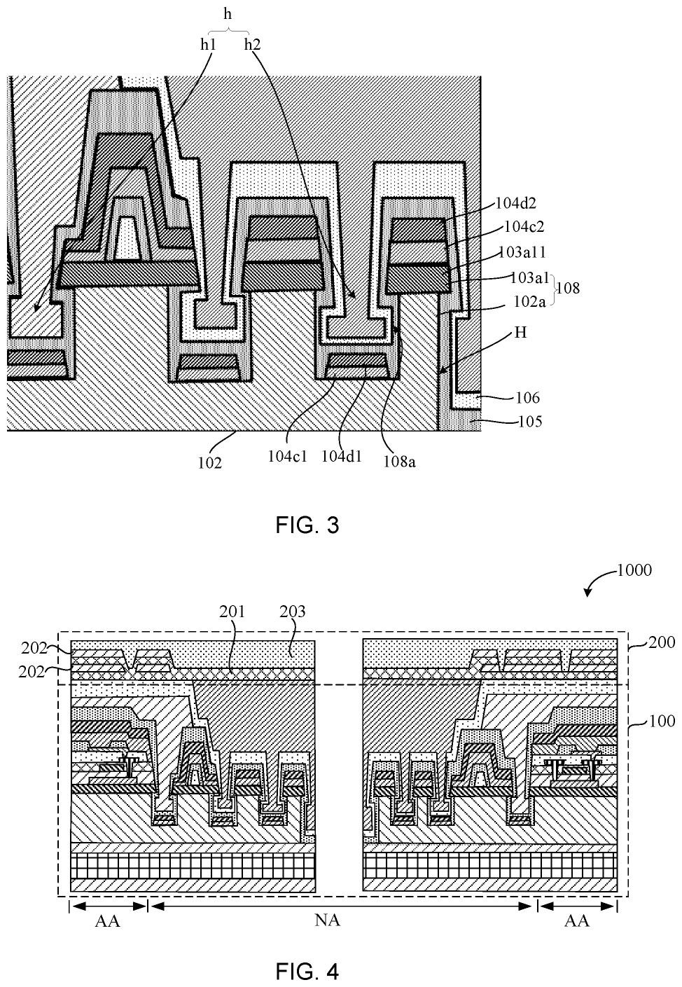

FIG. 3 is an enlarged view showing a B area of FIG. 2.

FIG. 4 is a structural schematic view showing a display device provided by an embodiment of the present disclosure.

### DETAILED DESCRIPTION OF EMBODIMENTS OF INVENTION

### Detailed Description of Invention

Embodiments are further described below in detail with reference to accompanying drawings to make objectives, technical solutions, and advantages of the present disclosure clearer and more precise. Examples of the described embodiments are given in the accompanying drawings, wherein the identical or similar reference numerals constantly denote the identical or similar elements or elements having the identical or similar functions. The specific embodiments described with reference to the attached drawings are all exemplary and are intended to illustrate and interpret the present disclosure, which shall not be construed as causing limitations to the present disclosure. A wording “embodiment” used in the present disclosure means an example or a demonstration.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

Embodiments of the present disclosure provide a display panel and a display device, which are respectively described below in detail. It should be noted that the description order of embodiments does not mean preferred orders of the embodiments.

Please refer to FIG. 1, FIG. 2, and FIG. 3. FIG. 1 is FIG. 1 is a plan structural view showing a display panel provided by an embodiment of the present disclosure. FIG. 2 is a structural schematic view showing a cross-section of FIG. 1 taken along A-A′. FIG. 3 is an enlarged view showing a B area of FIG. 2. An embodiment of the present disclosure provides a display panel. A display panel 100 includes a display area AA and a non-display area NA. The display area NA is defined on at least one side of the display area AA. The non-display area NA is provided with a through-hole TH. The through-hole TH is configured to contain components such as a camera, an earpiece, or a microphone.

It should be noted that, in some embodiments, the display area AA may be one side, two sides, three sides, or four sides of the non-display area NA. In the embodiment of the present disclosure, the display area AA surrounds a periphery of the non-display area NA, which is taken as a description example. The present disclosure is not limited to the description example.

The display panel 100 includes a substrate 101, a first flexible layer 102, a thin-film transistor (TFT) structural layer 103, a light-emitting functional layer 104, an opening H, a first inorganic layer 105, a second inorganic layer 106, an undercut structure 108, an organic filling layer 107, and an organic encapsulation layer 109.

Specifically, the first flexible layer 102 is disposed on the substrate 101. The TFT structural layer 103 is disposed on a surface of the first flexible layer 102 away from the substrate 101 in the display area AA. The light-emitting functional layer 104 is disposed on a surface of the TFT structural layer 103 away from the first flexible layer 102. The opening H is defined in the non-display area NA and penetrates the first flexible layer 102, the TFT structural layer 103, and the light-emitting functional layer 104. The first inorganic layer 105 is disposed on a surface of the light-emitting functional layer 104 away from the TFT structural layer 103 and at least covers a lateral wall of the opening H. The second inorganic layer 106 is disposed on a surface of the first inorganic layer 105 away from the light-emitting functional layer 104 and covers the first inorganic layer 105. The undercut structure 108 is disposed in the display area NA and is disposed on the substrate 101. The undercut structure 108 is provided with an undercut space.

In the display panel 100 provided by the embodiment of the present disclosure, the opening H is defined on a side of the display panel 100 close to the through-hole TH. Furthermore, the opening H penetrates the first flexible layer 102, the TFT structural layer 103, and the light-emitting functional layer 104. In addition, the first inorganic layer 105 covers the lateral wall of the opening H. As such, an issue of black spots formed at opening positions because moisture and oxygen enter the opening positions is solved.

It should be noted that an area where the through-hole TH is disposed includes, but is not limited to, a circular shape. For example, the area may further include a rectangular shape, a triangular shape, or an elliptical shape.

Furthermore, the first inorganic layer 105 covers a bottom of the opening H. In the embodiment of the present disclosure, the first inorganic layer 105 extends to the bottom of the opening H. Therefore, the opening H is completely covered by the first inorganic layer 105, thereby further preventing moisture and oxygen from entering the first flexible layer 102 from a lateral surface. As such, an issue of black spots formed at opening positions because moisture and oxygen enter the opening positions is solved, and a lifespan of encapsulation is extended.

In some embodiments, a material of the first inorganic layer 105 may be at least one of SiOₓ, SiNₓ, or SiOₓN_{y}. A material of the second inorganic layer 106 may be at least one of SiOₓ, SiNₓ, or SiOₓN_{y}.

The substrate 101 includes a backplate 101a, a second flexible layer 101b, and a blocking layer 101c. The second flexible layer 101b is disposed on the backplate 101a. The blocking layer 101c is disposed on a surface of the second flexible layer 101b away from the backplate 101a. The through-hole TH penetrates the backplate 101a, the second flexible layer 101b, and the blocking layer 101c.

The blocking layer 101c is configured to prevent moisture and oxygen from entering from a side of the backplate 101a to an upper structure of the blocking layer 101c, thereby preventing the display panel 100 from being damaged. A material of the blocking layer 101c includes, but is not limited to, silicon oxide, silicon nitride, or silicon oxynitride. For example, the material of the blocking layer 101c may be at least one of SiOₓ, SiNₓ, or SiOₓN_{y}. A material of the second flexible layer 101b may be same as that of the first flexible layer 102 and may include at least one of polyimide (PI), polyethylene terephthalate (PET), polyethylene naphthalate two formic acid glycol ester (PEN), polycarbonate (PC), polyethersulfone (PES), aromatic fluorotoluene including polyarylester (PAR), or polycyclic olefin (PCO).

The flexible layer 102 corresponding to the non-display area NA includes at least two recesses h. A protrusion part 102a is defined between two adjacent recesses h, The TFT structural layer 103 includes a buffer layer 103a. The buffer layer 103a is disposed on a surface of the first flexible layer 102 away from the substrate 101. The buffer layer 103a includes a spacer part 103a1 disposed in the non-display area NA. The protrusion part 102a and the spacer part 103a1 disposed above the protrusion part 102a form the undercut structure 108. The spacer part 103a1 includes a hovering part 103a11 protruding from the protrusion part 102a. The hovering part 103a11 and a lateral surface of the protrusion part 102a from the undercut space 108a. Any one of the recesses h is connected to the undercut space 108a. The first inorganic layer 105 covers the recesses h and the undercut structure 108.

The recesses h include a first recess h1 and a second recess h2. The first recess h1 is defined on a side of the second recess h2 away from the through-hole TH. The second recess h2 is defined close to the through-hole TH. The organic filling layer 107 fills the second recess h2. The organic encapsulation layer 108 is disposed between the first inorganic layer 105 and the second inorganic layer 106. The organic encapsulation layer 109 fills the first recess h1.

It should be noted that, in some embodiments, a material of the organic filling layer 107 and a material of the organic encapsulation layer 109 may be an organic material such as epoxy resin, polyimide (PI), polyethylene terephthalate (PET), polycarbonate (PC), polyethylene (PE), or polyacrylate. The material of the material of the organic filling layer 107 and the material of the organic encapsulation layer 109 may be same or different.

The TFT structural layer 103 may include the buffer layer 103a, an active layer 103b, a gate insulating layer 103c, a gate 103d, an interlayer dielectric layer 103e, a source 103f, a drain 103g, and a planarization layer 103h. The active layer 103b is disposed on the buffer layer 103a. The gate insulating layer 103c covers the active layer 103b and the buffer layer 103a. The gate 103d is disposed on the gate insulating layer 103c. The source 103f and the drain 103g are electrically connected to the active layer 103b by vias, respectively. The planarization layer 103h cover the source 103f and the drain 103g.

The active layer 103b may be an indium gallium zinc oxide (IGZO) active layer, a zinc tin oxide (ZTO) active layer, an indium tin zinc oxide (ITZO) active layer, or a low-temperature polycrystalline silicon (LTPS) active layer. A material of the gate 103c, a material of the source 103f, and a material of the drain 103g include one of Ag, Mg, Al, W, Cu, Ni, Cr, Mo, Ti, Pt, Ta, Nd, Sc, an alloy including thereof, or nitride including thereof. A material of the gate insulating layer 103c and a material of the interlayer dielectric layer 103e include one of silicon oxide, nitrogen oxide, silicon oxynitride, or a combination thereof. A material of the planarization layer 103h may be one of silicon dioxide, nitrogen dioxide, silicon oxynitride, a stacked layer including thereof, or an organic material such as acrylic.

It should be noted that the TFT structural layer 103 may be a bottom-gate TFT or a top-gate TFT. The structural layer 103 may be a single-gate TFT or a double-gate TFT. In the embodiment of the present disclosure, the top-gate TFT is taken as a description example. However, the present disclosure is not limited thereto.

The light-emitting functional layer 104 includes an anode 104a, a pixel defining layer 104b, a light-emitting layer 104c, and a cathode 104d, which are sequentially disposed. The anode 104a is electrically connected to the TFT structural layer 103. At least part of the light-emitting layer 104c is confined in an opening of the pixel defining layer 104b. The light-emitting layer 104c corresponding to the non-display area NA includes a first part 104c1 and a second part 104c2. The first part 104c1 of the light-emitting layer 104c and the second part 104c2 of the light-emitting layer 104c are separated from each other by the undercut space 108a. The first part 104c1 of the light-emitting layer 104c is disposed in the recesses h, and the second part 104c2 of the light-emitting layer 104c is disposed on the spacer part 103a. The cathode 104d corresponding to the non-display area NA includes a first part 104d1 and a second part 104d2. The first part 104d1 of the cathode 104d and the second part 104d2 of the cathode 104d are separated from each other by the undercut space 108a. The first part 104d1 of the cathode 104d is disposed on the first part 104c1 of the light-emitting layer 104c, and the second part 104d2 of the cathode 104d is disposed on the second part 104c2 of the light-emitting layer 104c.

A material of the anode 104a may be ITO. The light-emitting layer 104c is formed by ink-jet printing. A material of the light-emitting layer 104c may be an organic electroluminescent material, such as an organic electroluminescent material with high molecular weight or low molecular weight, a fluorescent compound, or a phosphorescent compound, which are commonly used in this field. A material of the cathode 104d may be at least one of Ag or Mg. The light-emitting functional layer 104 may further include other elements, such as a hole injection layer, a hole transport layer, an electron transport layer, or an electron injection layer, of organic light-emitting devices.

In the embodiment of the present disclosure, the undercut structure 108 is disposed on an area corresponding to the non-display area NA. Because a cross-section of the first flexible layer 102 is exposed because of the through-hole TH, moisture and oxygen are prone to enter from the exposed cross-section of the first flexible layer 102, causing the first inorganic layer 105 to be peeled off from corners of the undercut structure 108 of the display panel 100. This leads to deterioration, such as contraction, of the display panel 100. In the embodiment of the present disclosure, since the undercut structure 108 is disposed on an area corresponding to the non-display area, the light-emitting layer 104c is separated because of the undercut 108, which prevents moisture and oxygen from entering from the light-emitting layer 104c.

It should be noted that a number of the undercut structure 108 of the embodiment of the present disclosure rages from 2 to 12. In some embodiment, the number of the undercut structure 108 may be any one of 2, 3, 6, 9, 11, or 12. Since the undercut structure 108 of the embodiment of the present disclosure ranges from 2 to 12, failure of display panel 100, due to the light-emitting layer 104c unable to be separated at the undercut space 108a by only one undercut structure 108, is prevented.

In some embodiments, a width of the opening H is greater than or equal to 30 μm. For example, the width of the opening H may be any one of 30 μm, 35 μm, 40 μm, 45 μm, 50 μm, 60 μm, or 65 μm. In the embodiment of the present disclosure, since the width of the opening H is greater than or equal to 30 μm, precision of the opening H formed by cutting can be ensured.

Please refer to FIG. 2, the display panel 100 provided by the embodiment of the present disclosure may further include a barrier disposed between the first recess h1 and the second recess h2. The barrier includes the protrusion part 102a, the spacer part 103 disposed on the protrusion part 102a, the planarization layer 103h disposed above the spacer part 103a, the pixel defining layer 104b disposed above the planarization layer 103h, the light-emitting layer 104c disposed above the pixel defining layer 104b, and the cathode 104d disposed above the light-emitting layer 104c. It should be understood that the barrier of the present embodiment may be regarded as one undercut structure. Furthermore, the barrier is higher than the undercut structure 108, which can further extend a path where moisture and oxygen pass, thereby further improving stability of the display panel 100.

In some embodiments, the undercut structure 108 may be a ring-shaped undercut structure which at least includes a first undercut structure and a second undercut structure. The first undercut structure includes at least one first opening and surrounds the through-hole TH. The second undercut structure includes at least one second opening and surrounds the first undercut structure. At least part of the second opening corresponds to the first opening, which can shorten a path for discharging moisture, thereby reducing a coating period. Alternatively, the second opening and the first opening can be spaced apart from each other, which can extend a path where moisture and oxygen pass, thereby effectively preventing moisture and oxygen from entering.

It should be noted that the display panel 100 may be an active light-emitting display panel such as an organic light-emitting diode (OLED) display panel, an active-matrix organic light-emitting diode (AMOLED) display panel, a passive matrix organic light-emitting diode (PMOLED) display panel, a quantum-dot light-emitting diode (QLED) display panel, a micro light-emitting diode (micro-LED) display panel, or a mini light-emitting diode (mini-LED) display panel.

Please refer to FIG. 4, a structural schematic view showing a display device provided by an embodiment of the present disclosure is provided. The display device includes a display panel and a touch control unit 200. The touch control unit 200 is disposed on the display panel or is integrated into the display panel. The display panel can be the display panel 100 of the above-mentioned embodiment. A specific structure of the display panel can be referred to the above-mentioned embodiment and is not described here again.

The touch control unit 200 may include an inorganic silicon layer 201, a touch control layer 202, and an organic planarization layer 203. The touch control layer 202 is embedded into the inorganic silicon layer 201 and may have a double-layer structure. A material of the touch control layer 202 may be a stacked structure of Ti/Al/Ti. The touch control unit 200 is configured to realize capacitive touch.

It should be noted that the display device 1000 provided by the embodiment of the present disclosure may be a cell phone, a tablet, a notebook, or a television.

Embodiments of the present disclosure provide a display panel and a display device. The display panel provided by the present embodiment includes a substrate, a first flexible layer, a TFT structural layer, a light-emitting functional layer, an opening, and a first inorganic layer. The first inorganic layer is disposed on the substrate. The TFT structural layer is disposed on a surface of the first flexible layer away from the substrate and is disposed in a display area. The light-emitting functional layer is disposed on a surface of the TFT structural layer away from the first flexible layer. The opening is defined in a non-display area and penetrates the first flexible layer, the TFT structural layer, and the light-emitting functional layer. The first inorganic layer is disposed in a surface of the light-emitting functional layer away from the TFT structural layer and at least covers a lateral wall of the opening. In the display panel provided by the embodiment of the present disclosure, the opening is defined on a side close to a through-hole. The opening penetrates the first flexible layer, the TFT structural layer, and the light-emitting functional layer. The first inorganic layer covers the lateral wall of the opening. Therefore, an issue of black spots formed at opening positions because moisture and oxygen enter the opening positions is solved.

In summary, the present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

1. A display panel, comprising a display area and a non-display area, wherein the non-display area comprises a through-hole, and the display panel comprises:
a substrate;
a first flexible layer, wherein the first flexible layer is disposed on the substrate;
a thin-film transistor (TFT) structural layer, wherein the TFT structural layer is disposed on a surface of the first flexible layer away from the substrate and is disposed in the display area;
a light-emitting functional layer, wherein the light-emitting functional layer is disposed on a surface of the TFT structural layer away from the first flexible layer;
an opening, wherein the opening is defined in the non-display area and penetrates the first flexible layer, the TFT structural layer, and the light-emitting functional layer; and
a first inorganic layer, wherein the first inorganic layer is disposed on a surface of the light-emitting functional layer away from the TFT structural layer and at least covers a lateral wall of the opening.

2. The display panel of claim 1, wherein the first inorganic layer covers a bottom of the opening.

3. The display panel of claim 2, wherein the display panel comprises:
a second inorganic layer, wherein the second inorganic layer is disposed on a surface of the first inorganic layer away from the light-emitting functional layer, and the second inorganic layer covers the first inorganic layer.

4. The display panel of claim 3, wherein the display panel comprises:
an undercut structure disposed in the non-display area, wherein the undercut structure is disposed on the substrate and comprises undercut space.

5. The display panel of claim 4, wherein the first flexible layer corresponding to the non-display area comprises at least two recesses, and a protrusion part is defined between two adjacent recesses;
the TFT structural layer comprises a buffer layer, the buffer layer is disposed on a side of the first flexible layer away from the substrate, the buffer layer comprises a spacer part disposed in the non-display area, and the protrusion part and the spacer part disposed above the protrusion part form the undercut structure;
the spacer part comprises a hovering part protruding from the protrusion part, and the hovering part and a lateral surface of the protrusion part form the undercut space; and
the recesses are communicatively connected to the undercut space.

6. The display panel of claim 5, wherein the light-emitting functional layer comprises an anode, a pixel defining layer, a light-emitting layer, and a cathode, which are sequentially disposed, the anode is electrically connected to the TFT structural layer, and at least part of the light-emitting layer is confined in an opening of the pixel defining layer;
the light-emitting layer corresponding to the non-display area comprises a first part and a second part, the first part of the light-emitting layer and the second part of the light-emitting layer are separated apart from each other by the undercut space, the first part of the light-emitting layer is disposed in the recesses, and the second part of the light-emitting layer is disposed on the spacer part; and
the cathode corresponding to the non-display area comprises a first part and a second part, the first part of the cathode and the second part of the cathode are separated from each other by the undercut space, the first part of the cathode is disposed on the first part of the light-emitting layer, and the second part of the cathode is disposed on the second part of the light-emitting layer.

7. The display panel of claim 6, wherein the first inorganic layer covers the recesses and the undercut structure.

8. The display panel of claim 5, wherein the recesses comprise a first recess and a second recess, the first recess is defined on a side of the second recess away from the through-hole, and the second recess is defined on a side close to the through-hole, and the display panel comprises:
an organic filling layer, wherein the organic filling layer fills the second recess; and
an organic encapsulation layer, wherein the organic encapsulation layer is disposed between the first inorganic layer and the second inorganic layer, and the organic encapsulation layer fills the first recess.

9. The display panel of claim 1, wherein the substrate comprises:
a backplate;
a second flexible layer, wherein the second flexible layer is disposed on the backplate;
a blocking layer, wherein the blocking layer is disposed on a surface of the second flexible layer away from the backplate, and the through-hole penetrates the backplate, the second flexible layer, and the blocking layer.

10. The display panel of claim 1, wherein a width of the opening is greater than or equal to 30 μm.

11. A display device, comprising a touch control unit and a display panel, wherein the touch control unit is disposed on the display panel or is integrated into the display panel, the display panel comprises a display area and a non-display area, the non-display area comprises a through-hole, and the display panel comprises:
a substrate;
a first flexible layer, wherein the first flexible layer is disposed on the substrate;
a thin-film transistor (TFT) structural layer, wherein the TFT structural layer is disposed on a surface of the first flexible layer away from the substrate and is disposed in the display area;
a light-emitting functional layer, wherein the light-emitting functional layer is disposed on a surface of the TFT structural layer away from the first flexible layer;
an opening, wherein the opening is defined in the non-display area and penetrates the first flexible layer, the TFT structural layer, and the light-emitting functional layer; and
a first inorganic layer, wherein the first inorganic layer is disposed on a surface of the light-emitting functional layer away from the TFT structural layer and at least covers a lateral wall of the opening.

12. The display device of claim 11, wherein the first inorganic layer covers a bottom of the opening.

13. The display device of claim 12, wherein the display panel comprises:
a second inorganic layer, wherein the second inorganic layer is disposed on a surface of the first inorganic layer away from the light-emitting functional layer, and the second inorganic layer covers the first inorganic layer.

14. The display device of claim 13, wherein the display panel comprises:
an undercut structure disposed in the non-display area, wherein the undercut structure is disposed on the substrate and comprises undercut space.

15. The display device of claim 14, wherein the first flexible layer corresponding to the non-display area comprises at least two recesses, a protrusion part is defined between two adjacent recesses;
the TFT structural layer comprises a buffer layer, the buffer layer is disposed on a side of the first flexible layer away from the substrate, the buffer layer comprises a spacer part disposed in the non-display area, and the protrusion part and the spacer part disposed above the protrusion part form the undercut structure;
the spacer part comprises a hovering part protruding from the protrusion part, and the hovering part and a lateral surface of the protrusion part define the undercut space; and
the recesses are communicatively connected to the undercut space.

16. The display device of claim 15, wherein the light-emitting functional layer comprises an anode, a pixel defining layer, a light-emitting layer, and a cathode, which are sequentially disposed, the anode is electrically connected to the TFT structural layer, and at least part of the light-emitting layer is confined in an opening of the pixel defining layer;
the light-emitting layer corresponding to the non-display area comprises a first part and a second part, the first part of the light-emitting layer and the second part of the light-emitting layer are separated apart from each other by the undercut space, the first part of the light-emitting layer is disposed in the recesses, and the second part of the light-emitting layer is disposed on the spacer part; and
the cathode corresponding to the non-display area comprises a first part and a second part, the first part of the cathode and the second part of the cathode are separated from each other by the undercut space, the first part of the cathode is disposed on the first part of the light-emitting layer, and the second part of the cathode is disposed on the second part of the light-emitting layer.

17. The display device of claim 16, wherein the first inorganic layer covers the recesses and the undercut structure.

18. The display device of claim 15, wherein the recesses comprise a first recess and a second recess, the first recess is defined on a side of the second recess away from the through-hole, and the second recess is defined on a side close to the through-hole, and the display panel comprises:
an organic filling layer, wherein the organic filling layer fills the second recess; and
an organic encapsulation layer, wherein the organic encapsulation layer is disposed between the first inorganic layer and the second inorganic layer, and the organic encapsulation layer fills the first recess.

19. The display device of claim 11, wherein the substrate comprises:
a backplate;
a second flexible layer, wherein the second flexible layer is disposed on the backplate;
a blocking layer, wherein the blocking layer is disposed on a surface of the second flexible layer away from the backplate, and the through-hole penetrates the backplate, the second flexible layer, and the blocking layer.

20. The display device of claim 11, wherein a width of the opening is greater than or equal to 30 μm.
